(19) United States
(12) Patent Application Publication
(10) Pub. No.: US 2015/0033094 A1
(43) Pub. Date: Jan. 29, 2015

(54) WINDOW-STOPPED METHOD FOR APPLYING TO TURBO DECODING

(71) Applicant: Yuan Ze University, Chung-Li City (TW)

(72) Inventors: Cheng-Hung LIN, Chung-Li City (TW); Chih-Chia WEI, Chung-Li City (TW); Shu-Wei GUO, Chung-Li City (TW); Li-An OU, Chung-Li City (TW)

(73) Assignee: Yuan Ze University, Chung-Li City (TW)

(21) Appl. No.: 13/948,750

(22) Filed: Jul. 23, 2013

(51) Int. Cl. H03M 13/25

(52) U.S. Cl. CPC H03M 13/258
USPC 714/755

(57) ABSTRACT

A window-stopped method for applying to turbo decoding is disclosed, and proceeds a window detection to decoding information via a window-based detector and detects and records a convergent condition of each window of the decoding information when a turbo decoding is proceeded in every iteration operation and a soft-input soft-output decoder executes the turbo decoding.

### BACKGROUND OF THE INVENTION

1. Field of the Invention

The present invention generally relates to a window-stopped method for applying to turbo decoding, more particularly to a method that is applied to a turbo decoding algorithm in order to reduce the operation amount of inner windows of each iteration operation of the turbo decoding and to save unnecessary operation for lowering down power consumption.

2. Description of the Prior Art

Today's communication systems, forward error correction code (FEC) in the systems plays a very important role, and mainly protects data. Once the data are encoded by the error correction code modules, even the data are interfered by the noise in a transmission channel, correct information will be correctly received at a receiving end after a decoding process. The turbo code (TC) is now better one to correct the forward error correction code. The turbo code is accomplished by two soft-input soft-output decoders proceeding iteration operations, the two soft-input soft-output decoders can exchange probability information, so as to make coding gains approach Shannon Limit. Because of the excellent performance, turbo codes have been widely used in various wireless communication standards, such as DVB, WCDMA, LTE, WiMAX, etc., and can also be used in power line transmission systems, such as HomePlug.

Turbo code decoding is accomplished by the two soft-input soft-output algorithm decoders and an interleaver to exchange information between each other to perform iteration operations Through several iteration operations and mutual exchanges of information, the error correction capability is raised up. The current turbo decoder mostly adopts window decoding to save a lot of delays of turbo decoding and to improve throughput of turbo coding. But with the number of the iteration operations of the turbo decoder increased, the consumption of power also increases linearly, thereby shortening the time to use mobile devices.

Further, because of the application products of turbo code are for portable mobile devices, so that battery life is always the problem of mobile devices. However, with the number of the iteration operations of the turbo decoder increased, the consumption of power also increases linearly, thereby shortening the time to use mobile devices. In order to solve above problems, there are many studies proposed various early iteration termination technology, and the early iteration termination technology is a technology to effectively detect the excessive number of iteration operations, and it can early stop convergent turbo decodes and maintain the overall turbo code decoding performance. However, the early iteration termination technology stops the iteration operations of an overall turbo decoder when an entire information framework is convergent. Hence, before the conditions of the early iteration termination technology are approached, turbo decodes can not further stop the operations of inner decoding, and can not detect inner information and stop the operations.

Therefore, reducing the operation amount of inner windows of each iteration operation of turbo decoding is to save unnecessary operations and to lower down power consumption. During the turbo decoding process and after the soft-input soft-output decoding, window detection may be processed, in order to record the convergent conditions of inner windows of decoding information. So, for a next iteration operation, the inner operations of convergent windows are stopped to approach the purpose of lower power consumption of turbo decoding, which is a best solution.

### SUMMARY OF THE INVENTION

The main objective of the present invention is to provide a window-stopped method for applying to turbo decoding, and differs from that early iteration termination technology must stop overall iteration operations. The window-stopped technology is to detect windows after soft-input soft-output decoding of turbo decoding, so as to detect and record the conditions of each window of decoding information. Hence, for a next iteration operation, the internal operations of convergent windows can be stopped in order to reduce the operation amount of internal windows of each iteration operation of turbo decoding for saving unnecessary operations and lowering down power consumption.

The second objective of the present invention is to provide a window-stopped method for applying to turbo decoding, and for the operations of windows being stopped, extrinsic information exchanged with a next soft-input soft-output decoding is short of, the method can effectively use reliable information to let the turbo decoding work properly and keep an ability to correct errors when partial operation of the soft-input soft-output decoding is stopped.

To approach aforesaid objectives, the present invention proceeds a window detection to decoding information via a window-based detector and detects and records a convergent condition of each window of the decoding information when a turbo decoding is proceeded in every iteration operation and after a soft-input soft-output decoder executes the turbo decoding.

More specifically, a window generates soft information or hard information of decoded bits when the soft-input soft-output decoder proceeds a soft-input soft-output decoding, the window-based detector comparing the soft information or the hard information of the decoded bits of the window, so as to detect the convergent condition of each window.

More specifically, the window is recorded as a convergent window and the operation of the convergent window is stopped in a next iteration operation when the window-based detector determines that the overall window is all convergent.

More specifically, stopping the operation of the convergent window can use reliable information to be as exchanged extrinsic information in order to let the soft-input soft-output decoding work properly and keep an ability to correct errors when partial operation of the soft-input soft-output decoding is stopped.

More specifically, stopping the operation of the convergent window can use a memory to temporarily store extrinsic information in order to let the soft-input soft-output decoding work properly and keep an ability to correct errors when partial operation of the soft-input soft-output decoding is stopped.

More specifically, the decoding information has a plurality of parallel decoding kernels, the parallel decoding kernel being defined as a convergent kernel and the operation of the convergent kernel is stopped in a next iteration operation when the window-based detector determines that all windows of the parallel decoding kernel are convergent, the operation of the convergent kernel being stopped meaning that all operations of the decoding kernel are stopped.

More specifically, stopping the operation of the convergent kernel can use reliable information to be as exchanged extrinsic information in order to let the soft-input soft-output decoding work properly and keep an ability to correct errors when partial operation of the soft-input soft-output decoding is stopped.

More specifically, stopping the operation of the convergent kernel can use a memory to temporarily store extrinsic information in order to let the soft-input soft-output decoding work properly and keep an ability to correct errors when partial operation of the soft-input soft-output decoding is stopped.

### BRIEF DESCRIPTION OF THE DRAWINGS

The objects, spirits, and advantages of the preferred embodiments of the present invention will be readily understood by the accompanying drawings and detailed descriptions, wherein:

FIG. 1 illustrates a schematic structural view of a window-stopped method for applying to turbo decoding of the present invention;

FIG. 2 illustrates a schematic view of convergent windows and convergent kernels of the window-stopped method for applying to the turbo decoding of the present invention;

FIG. 3 illustrates a determining flow chart of the window-stopped method for applying to the turbo decoding of the present invention;

FIG. 4 illustrates a schematic comparison view of turbo decoders of a first embodiment of the window-stopped method for applying to the turbo decoding of the present invention;

FIG. 5 illustrates a schematic comparison view of power consumption of the first embodiment of the window-stopped method for applying to the turbo decoding of the present invention;

FIG. 6 illustrates a schematic comparison view of convergent window-stopped rates of the first embodiment of the window-stopped method for applying to the turbo decoding of the present invention;

FIG. 7 illustrates a schematic view of the numbers of parallel decoding kernels and windows of an information framework of a second embodiment of the window-stopped method for applying to the turbo decoding of the present invention;

FIG. 8 illustrates a schematic symbol standard view of WRR and KRR of a noise rate of the second embodiment of the window-stopped method for applying to the turbo decoding of the present invention; and

FIG. 9 illustrates a schematic comparison view of power rates of non-convergent window, convergent window and convergent kernel of the second embodiment of the window-stopped method for applying to the turbo decoding of the present invention.

### DETAILED DESCRIPTION OF THE INVENTION

Following preferred embodiments and figures will be described in detail so as to achieve aforesaid objects.

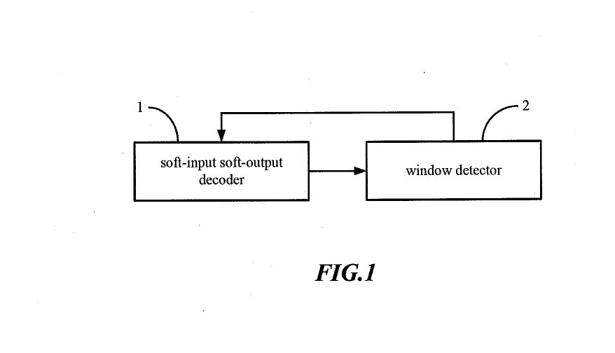

Please refer to FIG. 1, which illustrates a schematic structural view of a window-stopped method for applying to turbo decoding of the present invention. As shown in figure, the window-stopped technique provided by the present invention is to effectively detect the convergent condition of each bit. A window-based detector (WBD) 2 plugs into a soft-input soft-output decoder 1 in order to detect that whether the value of a maximum posterior (MAP) probability of each point of a single window is greater than a predetermined threshold limit value. When the value of a maximum posterior probability is greater than a predetermined threshold limit value, decoded information being correct can be assumed, and the decoded information being convergent is determined. The window-based detector 2 is able to run a window computing stop technology and a kernel-stopped (KS) technology.

The window-based detector 2 may record that the window is a convergent window when the overall windows are convergent, and stop the operation of the convergent window in order to decrease energy consumption.

While in a turbo decoding process, a forward recursion arithmetic unit may calculate and store the last bit of each parallel decoding framework. For a next iteration operation, the last bit may be read to the forward recursion arithmetic unit of the next iteration operation as an initialize value. A backward recursion arithmetic unit may calculate and store the last bit of each window. For a next iteration operation, the last bit of a this iteration operation may be read to the backward recursion arithmetic unit as an initialize value. However, only stopping the operation of a window may not stop the forward recursion arithmetic unit, and the forward recursion arithmetic unit continuously calculates in order to provide a reliable initialize value to a next window. However, the present invention again takes the window computing stop technology as a base to extend the kernel-stopped technology. If all windows of an MAP decoding kernel are convergent, the decoding kernel can be defined as a convergent kernel. The convergent kernel will stop operations in a next iteration operation. The operation of a kernel being stopped means that all operations of the kernel are stopped, and the all operations include the all operations of all windows and the forward recursion arithmetic unit.

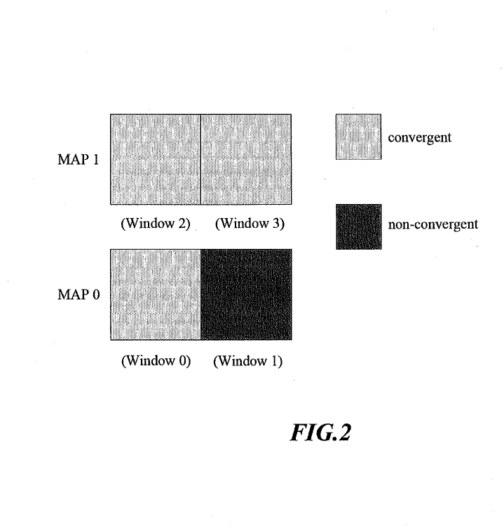

As shown in FIG. 2, if a turbo decoder has two MAP decoding kernels, MAP0 and MAP1. Each MAP decoding kernel has two windows, Windows 0, 1 and Windows 2, 3. MAP0 has a convergent window, Window 0, and a non-convergent window, Window 1, and MAP1 has two convergent windows, Windows 2, 3, hence MAP1 can be defined as a convergent decoding kernel.

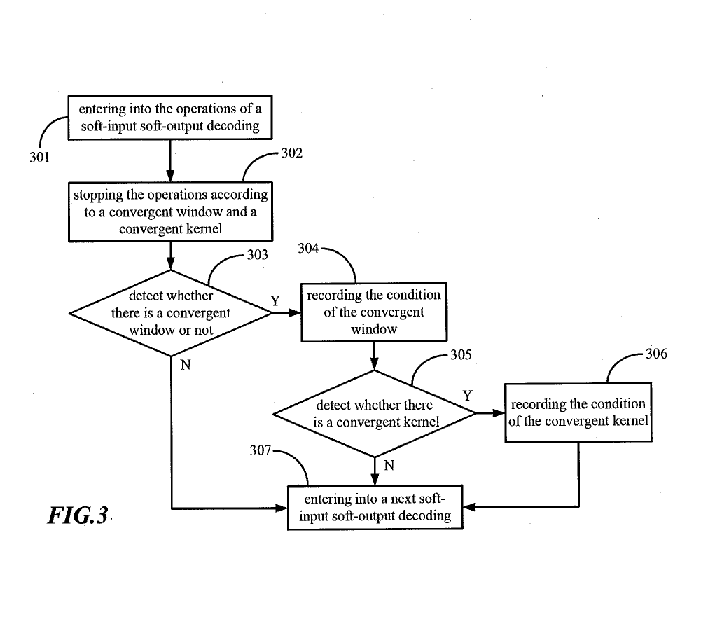

As shown in FIG. 3, which illustrates a determining flow chart of the window-stopped method for applying to the turbo decoding of the present invention. The method in the iteration operation of a turbo decoding comprises the steps of:
(301) entering into the operations of a soft-input soft-output decoding;
(302) stopping the operations according to a convergent window and a convergent kernel of last recording;
(303) using the window computing stop technology to detect whether there is a convergent window or not, if yes, going to (304), if no, going to (307);
(304) recording the condition of the convergent window;
(305) using the kernel-stopped technology to detect whether there is a convergent window or not, if yes, going to (306), if no, going to (307);
(306) recording the condition of the convergent kernel; and
(307) entering into the operations of a next soft-input soft-output decoding.

Besides, for stopping the operations of windows or kernels and lack of extrinsic information exchanging with a next soft-input soft-output decoding, the present invention adopts an external memory to temporarily store and exchange extrinsic information or reliable information that can be as switched extrinsic information in order to let the soft-input soft-output decoding work properly and keep an ability to correct errors when partial operation of the soft-input soft-output decoding is stopped.

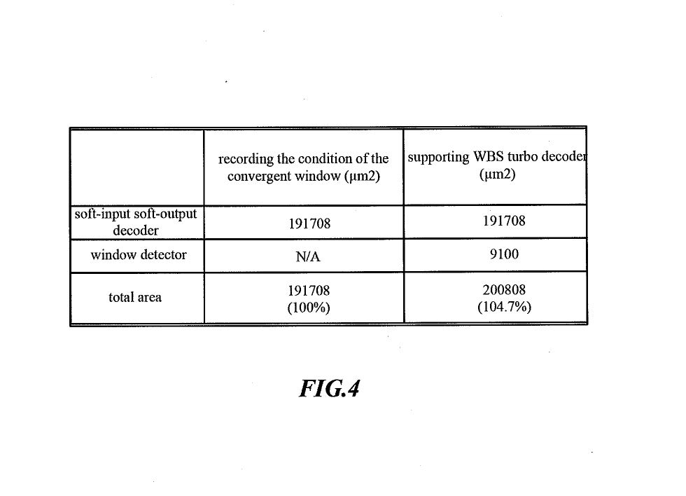

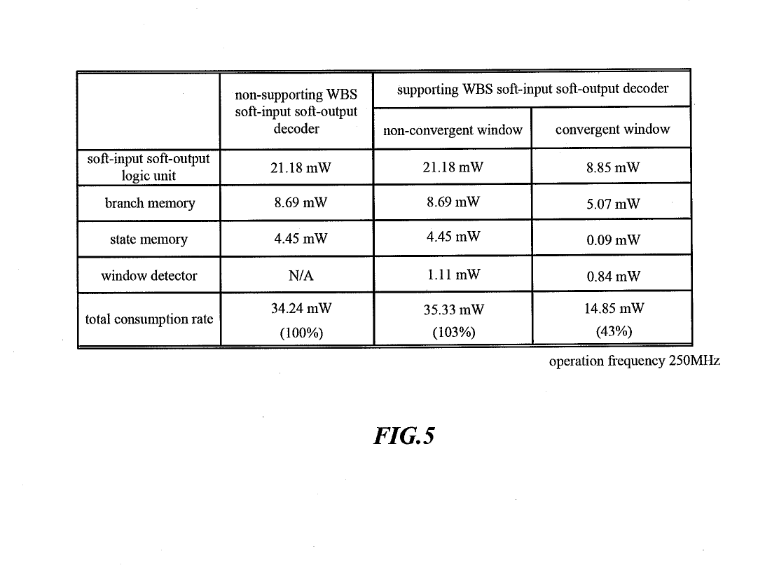

The present invention adopts two turbo code mechanisms, WiMAX and HomePlug, as two embodiments, and uses sliding window to enhance max-log maximum a posteriori algorithm (ELM-MAP) in order to proceed the turbo decoding. The first embodiment is WiMAX, and adopts a single decoding kernel to detect the convergent condition of a window. The decoder uses the turbo code standard of WiMAX communication standard. The maximum time of iteration is 8 and the additive white Gaussian noise channel can be a simulated condition while under 1920 bits of information framework. For hardware, the embodiment adopts TSMC 90 nanometer process to proceed a synthesis simulation verification. Under the operation frequency of 250 MHz and via the synthesis of Synopsys Design Vision software and the analysis of power consumption of Synopsys Prime Power, area and analysis of power consumption are shown in FIG. 4 and FIG. 5. SISO logic in FIG. 5 is a soft-input soft-output logic unit, which includes a forward recursion arithmetic unit, a backward recursion arithmetic unit and a posteriori arithmetic unit.

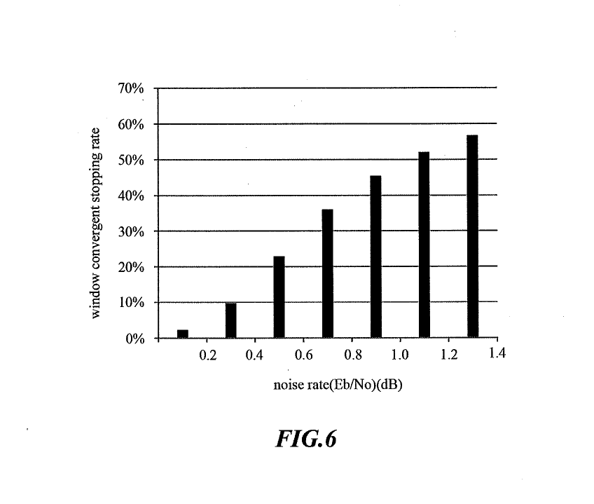

As shown in FIG. 5 and FIG. 6, through the present invention, although the turbo decoder supporting the window-based stopping (WBS) technology may need 4.7% of additional area and the window-based detector 2 additionally consumes power to detect the convergent condition of each bit. However, for a convergent window, the present invention may additionally decrease 57% of power consumption. With reference to FIG. 5 and FIG. 6, after E_{b}/N₀=0.4 dB, the saved power consumption is greater than the increased power, the balance of area and power is acceptable while in a good transmission quality.

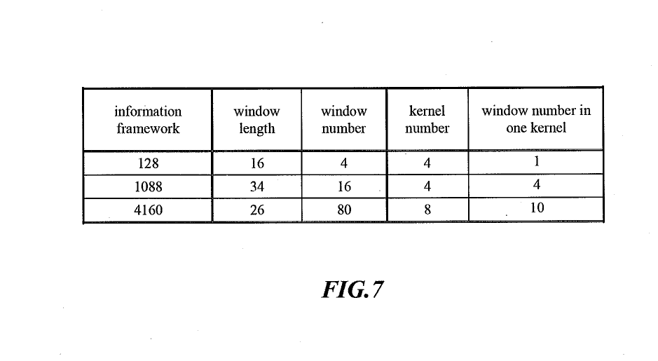

The second embodiment is the HomePlug turbo code mechanism, and detects the conditions of a convergent kernel and a convergent window. The decoder adopts the turbo code standard of HomePlug communication standard, and uses three lengths of information framework, 128, 1088 and 4160. The maximum time of iteration is 8 and the additive white Gaussian noise channel can be a simulated condition. As shown in FIG. 7, the number of the parallel decoding kernel of each information framework, the number of windows of a kernel and the length of each window are different. According to figure, the number of windows of a kernel is decided by the lengths of the windows and the number of the parallel decoding kernels. The lengths of the windows decide the difficulty of the conditions of the window-stopped, and the plural windows of the kernels decide the difficulty of the conditions of the kernel-stopped.

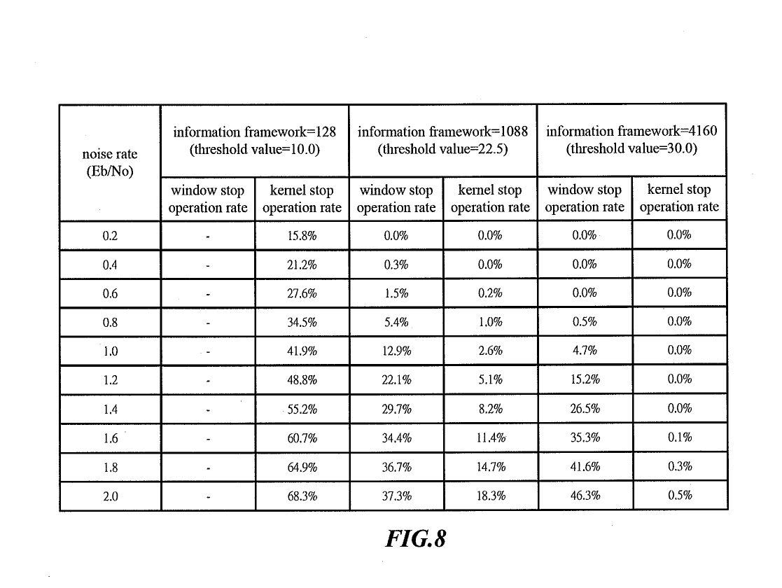

To calculate the saved operation amount of convergent windows and kernels, a window reduction rate (WRR) and a kernel reduction rate (KRR) are defined here. A total reduction rate is the sum of the window reduction rate and the kernel reduction rate. As shown in FIG. 8, the stopped windows of the window reduction rates and the kernel reduction rates are not repeatedly calculated, and the window reduction rates, and the kernel reduction rates of the noise rates are shown in figure.

In addition, to analyze the turbo decoder, the present invention adopts TSMC 90 nanometer process. The operation frequency of Synopsys Design Vision is 250 MHz. For saving more power consumption, the present invention integrates the window-stopped technology, the kernel-stopped technology and the early iteration termination technology, wherein the early iteration termination technology detects convergent iteration operations, and then stops the operations of overall turbo decoding. For non-convergent iteration operations, the kernel-stopped technology detects convergent kernels, and then stops the operations of the convergent kernels. The window-stopped technology detects convergent windows, and then stops the operations of the convergent windows. Aforesaid convergent windows and kernels are not overlapped.

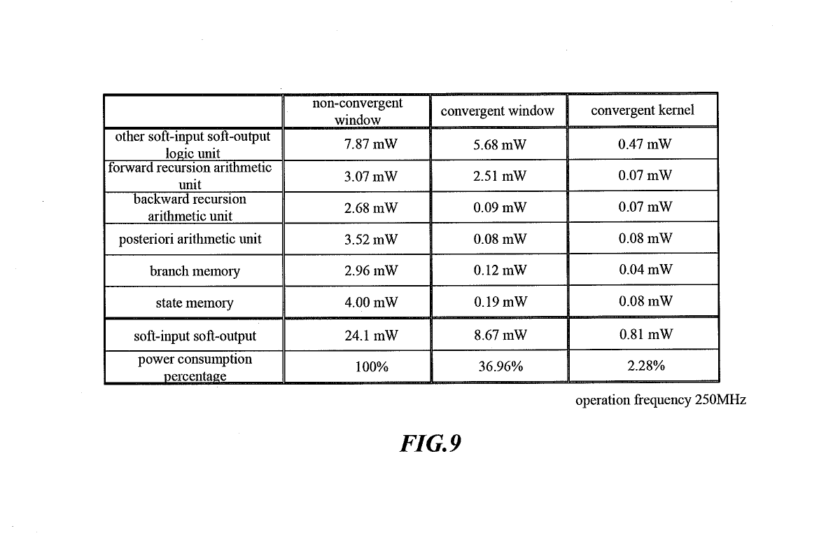

Please refer to FIG. 9, which shows the practical saved power rate of verifying each stopped operation unit. The non-convergent window, the convergent window and the convergent kernel all use power rates measured by Synopsys Prime Power, wherein there are other SISO logic, forward recursion arithmetic unit, backward recursion arithmetic unit, posteriori arithmetic unit, BMC, SMM, SISO, and overall power rate. The SISO logic includes branch operation unit, register, control signal, and control unit, the other SISO logic excludes forward recursion arithmetic unit, backward recursion arithmetic unit and posteriori arithmetic unit, and only includes residue control unit, so the SISO logic is different than the SISO logic in FIG. 5.

As shown in FIG. 9, compared to the non-convergent windows, the convergent windows save around 63% of power rate. The convergent kernels provided by the present invention further save 97% of power rate.

Compared to prior arts, the window-stopped method for applying to turbo decoding provided by the present invention has following advantages listed below:
1. The present invention is able to decrease the operation amount of internal windows in every iteration operation of turbo decoding, and to save unnecessary operations in order to lower down the power consumption. During the turbo decoding, soft-input soft-output decoding detects windows and records the convergent conditions of each window of decoding information. Hence, for a next iteration operation, the operations of convergent windows may be stopped in order to lower down the power consumption of turbo decoding.
2. The present invention is different than early iteration termination technology, which is able to stop overall iteration operations. Before the conditions of the early iteration termination technology are approached, the turbo decoding cannot further stop the operations of internal decoding. The present invention provides window-stopped (WS) technology in order to determine the convergent conditions of window decoding via the information of detecting soft-input soft-output decoding. When the overall windows are converged, the convergent windows will be recorded as convergent windows, and the operations of the convergent windows are stopped in the next decoding operations, so as to reduce power consumption.
3. The convergent windows and the convergent kernels detected by the present invention are not overlapped, so the present invention differs from the early iteration termination technology, and is capable of additionally detecting partially convergent windows before the overall information framework is converged, and stopping the operations, so as to lower down power consumption.

Although the invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A window-stopped method for applying to turbo decoding, which proceeds a window detection to decoding information via a window-based detector and detects and records a convergent condition of each window of the decoding information when a turbo decoding is proceeded in every iteration operation and a soft-input soft-output decoder executes the turbo decoding.

2. The window-stopped method for applying to the turbo decoding according to claim 1, wherein a window generates soft information or hard information of decoded bits when the soft-input soft-output decoder proceeds a soft-input soft-output decoding, the window-based detector comparing the soft information or the hard information of the decoded bits of the window, so as to detect the convergent condition of each window.

3. The window-stopped method for applying to the turbo decoding according to claim 2, wherein the window is recorded as a convergent window and the operation of the convergent window is stopped in a next iteration operation when the window-based detector determines that the overall window is all convergent.

4. The window-stopped method for applying to the turbo decoding according to claim 3, wherein stopping the operation of the convergent window can use reliable information to be as exchanged extrinsic information in order to let the soft-input soft-output decoding work properly and keep an ability to correct errors when partial operation of the soft-input soft-output decoding is stopped.

5. The window-stopped method for applying to the turbo decoding according to claim 3, wherein stopping the operation of the convergent window can use a memory to temporarily store extrinsic information in order to let the soft-input soft-output decoding work properly and keep an ability to correct errors when partial operation of the soft-input soft-output decoding is stopped.

6. The window-stopped method for applying to the turbo decoding according to claim 2, wherein the decoding information has a plurality of parallel decoding kernels, the parallel decoding kernel being defined as a convergent kernel and the operation of the convergent kernel is stopped in a next iteration operation when the window-based detector determines that all windows of the parallel decoding kernel are convergent, the operation of the convergent kernel being stopped meaning that all operations of the decoding kernel are stopped.

7. The window-stopped method for applying to the turbo decoding according to claim 6, wherein stopping the operation of the convergent kernel can use reliable information to be as exchanged extrinsic information in order to let the soft-input soft-output decoding work properly and keep an ability to correct errors when partial operation of the soft-input soft-output decoding is stopped.

8. The window-stopped method for applying to the turbo decoding according to claim 6, wherein stopping the operation of the convergent kernel can use a memory to temporarily store extrinsic information in order to let the soft-input soft-output decoding work properly and keep an ability to correct errors when partial operation of the soft-input soft-output decoding is stopped.
